(19) United States
(12) Patent Application Publication
(10) Pub. No.: US 2023/0187268 A1
(43) Pub. Date: Jun. 15, 2023

(54) SEMICONDUCTOR DEVICE AND METHOD FOR MANUFACTURING SAME

(71) Applicant: DB HiTek Co., Ltd., Bucheon-si (KR)

(72) Inventor: Dong Hoon Park, Uiwang-si (KR)

(21) Appl. No.: 18/073,536

(22) Filed: Dec. 1, 2022

(30) Foreign Application Priority Data
Dec. 15, 2021 (KR) 10-2021-0179471

(51) Int. Cl. H01L 21/764; H01L 29/06; H01L 29/10; H01L 29/78; H01L 29/66

(52) U.S. Cl. CPC H01L 21/764; H01L 29/0649; H01L 29/1095; H01L 29/7816; H01L 29/66681

(57) ABSTRACT

Provided is a semiconductor device and a method of manufacturing the same and, more particularly, to a semiconductor device and a method of manufacturing the same seeking to simplify the manufacturing process and consequently improve efficiency and reliability by forming an isolation region (191) including a pre-DTI region (1911) and a DTI region (1913) in and/or on a substrate before depositing an interlayer dielectric, thereby avoiding a need for a separate etch stop layer.

### CROSS REFERENCE TO RELATED APPLICATION

The present application claims priority to Korean Patent Application No. 10-2021-0179471, filed Dec. 15, 2021, the entire contents of which are incorporated herein for all purposes by this reference.

### BACKGROUND OF THE INVENTION

### Field of the Invention

The present disclosure relates to a semiconductor device and a method of manufacturing the same and, more particularly, to a semiconductor device and a method of manufacturing the same, seeking to simplify processing and consequently improve efficiency and reliability by forming an isolation region comprising a pre-DTI region and a DTI region on a substrate, then depositing an interlayer dielectric, to avoid use of a separate etch stop layer.

### Description of the Related Art

In recent bipolar-CMOS-DMOS (BCD) semiconductor manufacturing processes, it is desirable to achieve a breakdown voltage of 100V or more for the DMOS transistors. According to this target breakdown voltage, a deep trench isolation (DTI) region can reduce or minimize leakage current by electrically isolating adjacent devices.

FIG. 1 is a cross-sectional view for reference showing a DTI region in a conventional semiconductor device.

Referring to FIG. 1, a DTI region 910 used for electrical isolation between adjacent devices includes a trench region formed by etching a substrate 901 to a predetermined depth in a single etching process, then filling the resulting trench with an insulating material. When the DTI region 910 is formed by a single etching process as described above, there may be technical limitations in forming the deep trench. That is, when the DTI region is formed by etching the substrate 901 in a single process, it is not easy to form the trench sufficiently deep to electrically isolate the adjacent devices. In particular, when the trench is not sufficiently deep to achieve a breakdown voltage (BV) of 100V or more, the breakdown voltage characteristics may deteriorate due to an increase in the electric field area to the region of the substrate 901 below the DTI region 910 and an increase in the leakage current. In addition, as the separation distance between transistor devices increases in order to reduce or prevent transmission of noise between the adjacent devices, the overall chip size inevitably increases.

To solve the above-mentioned problems, the present disclosure concerns a novel semiconductor device having an improved structure and a method of manufacturing the same, described below.

### DOCUMENT OF RELATED ART

Korean Patent Application Publication No. 10-2003-0000592, entitled “METHOD OF MANUFACTURING SEMICONDUCTOR DEVICE WITH STI/DTI STRUCTURE.”

### SUMMARY OF THE INVENTION

The present disclosure has been made to solve the problems of the related art, and an objective of the present disclosure is to provide a semiconductor device and a method of manufacturing the same that improve isolation characteristics between adjacent devices, thereby improving device characteristics and reducing chip size by extending an isolation region to relatively deep in a substrate by separately forming a first trench having a first, relatively large width (e.g., a “pre-DTI region”) and a second, relatively narrow trench (i.e., the DTI region). The second trench may overlap completely with the first trench.

Moreover, an objective of the present disclosure is to provide a semiconductor device and a method of manufacturing the same that ensure process simplification and reliability by excluding a separate etch stop layer (such as a SiN film) and forming an isolation region by depositing an insulating layer on a substrate with a gate layer thereon, and then removing the insulating layer.

Furthermore, an objective of the present disclosure is to provide a semiconductor device and a method of manufacturing the same that prevent metals such as tungsten from remaining on the isolation region during a subsequent process for forming a contact, etc., by depositing an interlayer dielectric on the substrate to cover the isolation region (e.g., after the isolation region is formed.

According to one or more embodiments of the present disclosure, there is provided a semiconductor device including a substrate; a gate electrode on the substrate; a shallow trench isolation (STI) region in the substrate; an isolation region including a pre-deep trench isolation (DTI) region that at least partially overlaps with the STI region (e.g., in a vertical direction, relative to an uppermost surface of the substrate defining a horizontal or substantially horizontal plane), and a DTI region extending from the pre-DTI region into the substrate; and an interlayer dielectric on the substrate that may cover the pre-DTI region.

According to one or more other or further embodiments of the present disclosure, in the semiconductor device of the present disclosure, at least part of the isolation region may pass through the interlayer dielectric (e.g., the interlayer dielectric may be deposited on the substrate after the isolation region is formed).

According to one or more other or further embodiments of the present disclosure, in the semiconductor device of the present disclosure, the DTI region may have a smaller width than that of the pre-DTI region.

According to one or more other or further embodiments of the present disclosure, the semiconductor device of the present disclosure may further include an air gap in the isolation region, at least partially (if not entirely) below the pre-DTI region.

According to one or more other or further embodiments of the present disclosure, in the semiconductor device of the present disclosure, the DTI region may be formed before the gate electrode is formed. Alternatively, each of the gate electrode and at least part of the DTI region may be on or above an uppermost surface of the substrate.

According to one or more other or further embodiments of the present disclosure, the semiconductor device of the present disclosure may further include a first buried layer having a second conductivity type in the substrate; a deep well directly or indirectly connected to the first buried layer having the second conductivity type; a first well in the deep well; a drain in the first well and at a surface of the substrate; a body region having a first conductivity type in the substrate; and a source in the body region and at the surface of the substrate.

According to one or more other or further embodiments of the present disclosure, the semiconductor device of the present disclosure may further include a second buried layer having the first conductivity type in the substrate; and a high-voltage well having the second conductivity type connected to the second buried layer and the deep well.

According to one or more other or further embodiments of the present disclosure, in the semiconductor device of the present disclosure, the pre-DTI region may be at least partially below an adjacent gate electrode.

According to one or more other or further embodiments of the present disclosure, the semiconductor device of the present disclosure may further include a dummy gate on the STI region, and the pre-DTI region may at least partially overlap with the dummy gate.

According to one or more other or further embodiments of the present disclosure, in the semiconductor device of the present disclosure, the DTI region may have a lowermost surface below the buried layer.

According to one or more embodiments of the present disclosure, there is provided a method of manufacturing a semiconductor device. The method includes depositing a gate layer on a substrate containing a shallow trench isolation (STI) region; forming a first trench by etching the gate layer (e.g., on or over the STI region) and the STI region; forming a second trench by etching the substrate under or exposed by the first trench; depositing a first insulating layer in the first trench and the second trench (e.g., along sidewalls of the first and second trenches); and forming an isolation region by filling the first trench and the second trench with a second insulating layer.

According to one or more other or further embodiments of the present disclosure, the method of manufacturing a semiconductor device of the present disclosure may further include forming a gate electrode by etching the gate layer (e.g., after forming the isolation region).

According to one or more other or further embodiments of the present disclosure, the method of manufacturing a semiconductor device of the present disclosure may further include depositing an interlayer dielectric on the substrate to cover the gate electrode and the isolation region.

According to one or more other or further embodiments of the present disclosure, in the method of manufacturing a semiconductor device of the present disclosure, etching the gate layer may further form a dummy gate on the STI region.

According to one or more other or further embodiments of the present disclosure, a method of manufacturing a semiconductor device of the present disclosure may include depositing a gate layer on a substrate containing an STI region; forming an isolation region containing an air gap, wherein at least part of the isolation region passes through the gate layer and the STI region; forming a gate electrode by etching the gate layer; and depositing an interlayer dielectric on the substrate (and, optionally, on the gate electrode).

According to one or more other or further embodiments of the present disclosure, in the method of manufacturing a semiconductor device of the present disclosure, forming the isolation region may include forming a pre-deep trench isolation (DTI) region at least partially overlapping the STI region; and forming a DTI region to a predetermined depth in the substrate (e.g., under the pre-DTI region or in an area of the substrate exposed by the pre-DTI region).

According to one or more other or further embodiments of the present disclosure, in the method of manufacturing a semiconductor device of the present disclosure, forming the pre-DTI region may include forming a first trench by etching the gate layer exposed by a first photoresist pattern (and, optionally, the STI under the gate layer), and forming the DTI region may include forming a second trench having a smaller width than that of the first trench by etching the substrate exposed by a second photoresist pattern on the gate layer and on sidewalls of the first trench.

According to one or more other or further embodiments of the present disclosure, in the method of manufacturing a semiconductor device of the present disclosure, forming the pre-DTI region and forming the DTI region may further include depositing a first insulating layer on the gate layer and in the first and second trenches; etching (e.g., anisotropically etching) the first insulating layer on the gate layer; depositing a second insulating layer on the gate layer and in the first and second trenches; and removing the second insulating layer on the gate layer.

According to one or more other or further embodiments of the present disclosure, in the method of manufacturing a semiconductor device of the present disclosure, the interlayer dielectric may be deposited after forming the isolation region.

According to one or more other or further embodiments of the present disclosure, in the method of manufacturing a semiconductor device of the present disclosure, the isolation region may have a lowermost surface at a depth of about 30 μm or more from a surface (e.g., the uppermost surface) of the substrate.

The above configurations may have one or more of the following effects.

The present disclosure can improve isolation characteristics between adjacent devices, thereby improving device characteristics and reducing chip size by allowing an isolation region to easily extend deeply into a substrate by separately forming a first trench having a relatively large width (e.g., a “pre-DTI” region) and a second trench having a relatively narrow width (e.g., the DTI region).

Moreover, the present disclosure can simplify the manufacturing process and ensure device reliability by excluding a separate etch stop layer (such as a SiN film) and forming an isolation region by depositing an insulating layer on a gate layer on a substrate, and then removing the insulating layer on the gate layer.

Furthermore, the present disclosure can prevent metals such as tungsten from remaining on the isolation region during subsequent processing to form a contact, etc., by depositing an interlayer dielectric on the substrate to cover the isolation region after the isolation region is formed.

Meanwhile, it should be added that even if effects are not explicitly mentioned herein, the effects described in the following specification expected by the technical features of the present disclosure and their potential effects are treated as if they were described in the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view for reference showing a DTI region in a conventional semiconductor device;

FIG. 2 is a cross-sectional view of a semiconductor device according to one or more embodiments of the present disclosure;

FIG. 3 is a cross-sectional view showing a dummy gate in the semiconductor device illustrated in FIG. 2;

FIG. 4 is a reference view showing isolation characteristics according to the depth of an isolation region (or a DTI region); and

FIGS. 5 to 13 are cross-sectional views showing a method of manufacturing a semiconductor device according to one or more embodiments of the present disclosure.

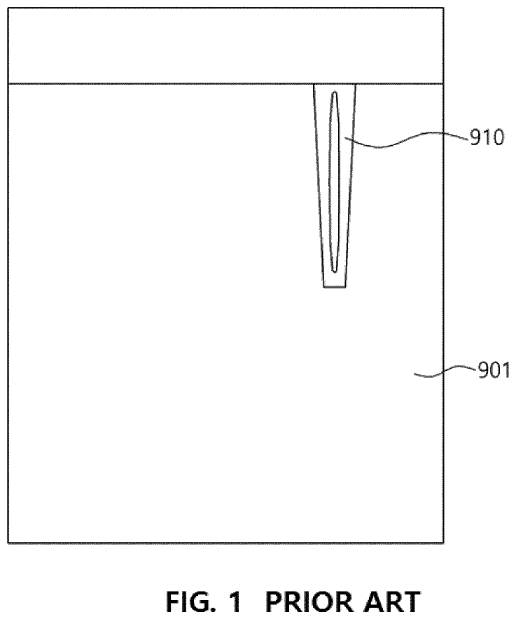

### DETAILED DESCRIPTION OF THE INVENTION

Hereinafter, embodiments of the present disclosure will be described in more detail with reference to the accompanying drawings. Embodiments of the present disclosure may be modified in various forms, and the scope of the present disclosure should not be construed as being limited to the following embodiments, but should be construed based on the matters described in the claims. In addition, these embodiments are provided for reference in order to more completely explain the present disclosure to those of ordinary skill in the art.

Hereinafter, it should be noted that when one component (or layer) is described as being on another component (or layer), the one component may be directly on another component, or one or more further component(s) or layer(s) may be between the one component and the other component. In addition, when one component is expressed as being directly on or above another component, no other component(s) are between the components. Moreover, being located “on top”, “above”, “below”, “on”, “under” or “on one (a first) side” or “on opposite sides” of a component means a relative positional relationship.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

The term a metal oxide semiconductor (MOS) used below is a general term, and “M” is not limited to only metal, and may refer to various types of conductors. Also, “S” may be a substrate or a semiconductor structure, and “0” is not limited to oxide, and may include various types of organic or inorganic insulating materials.

Moreover, the conductivity type of a doped region or component may be defined as “p-type” or “n-type” according to the main carrier characteristics, but this is only for convenience of description, and the technical spirit of the present disclosure is not limited to what is illustrated. For example, hereinafter, “p-type” or “n-type” may be replaced with the more general terms “first conductivity type” or “second conductivity type”, and here, the first conductivity type may refer to p-type, and the second conductivity type may refer to n-type.

Furthermore, it should be understood that “high concentration” and “low concentration” referring to the doping concentration of the impurity region mean the relative doping concentration of one component to one or more other components.

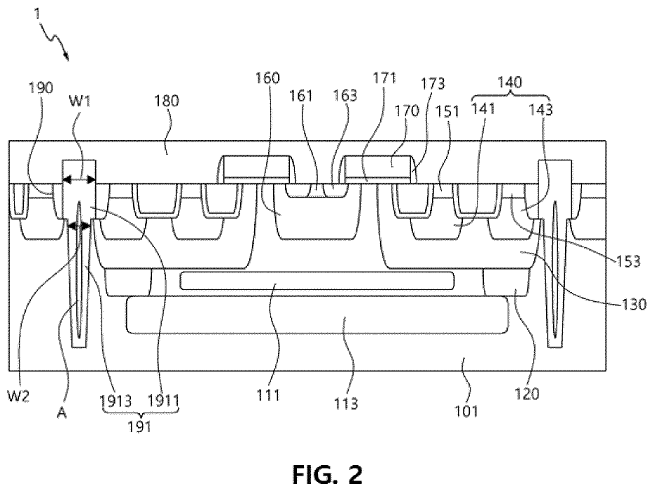

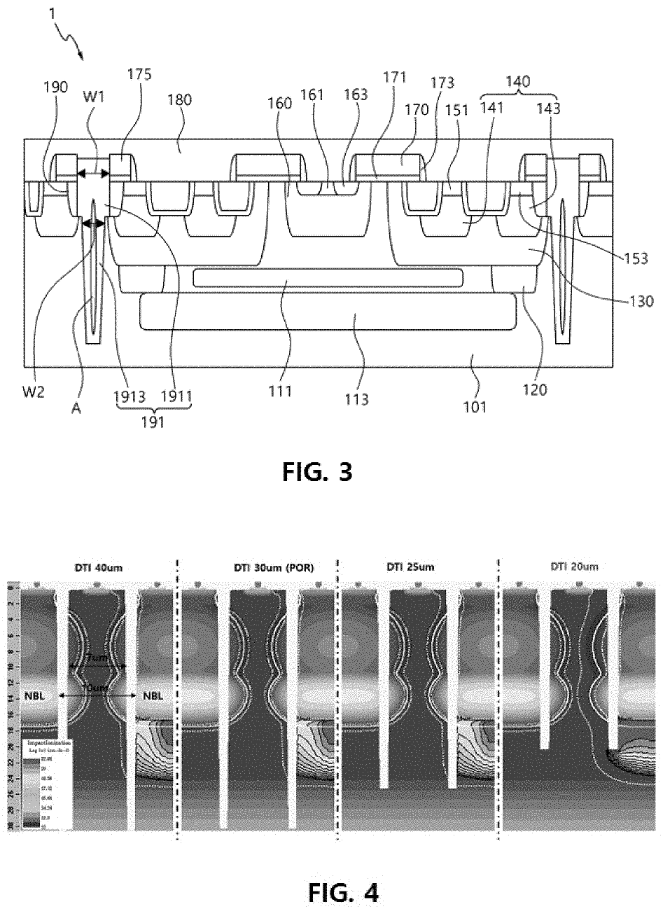

FIG. 2 is a cross-sectional view of a semiconductor device according to one or more embodiments of the present disclosure, and FIG. 3 is a cross-sectional view showing a dummy gate in the semiconductor device illustrated in FIG. 2.

Hereinafter, a semiconductor device 1 according to one or more embodiments of the present disclosure will be described in detail with reference to the accompanying drawings.

Referring to FIG. 2, the present disclosure relates to the semiconductor device 1 and, more particularly, to the semiconductor device 1 including an isolation region 191 comprising a pre-deep trench isolation (pre-DTI) region 1911 and a DTI region 1913 on a substrate. The isolation region 191 may be formed without a separate etch stop layer, thereby ensuring a relatively simple manufacturing processes and improved efficiency and reliability. Details will be described below.

As will be described in detail below, the isolation region 191 according to one or more embodiments of the present disclosure is completed before forming a gate electrode and/or a dummy gate.

Now, the structure of the semiconductor device 1 will be described. First, the substrate 101 may include a well (not shown or identified) used as an active region on or in the substrate 101, and this active region may be defined by a shallow trench isolation (STI) region 190. The substrate 101 may comprise a single crystal (e.g., monolithic) silicon wafer doped with a first conductivity type dopant, a P-type diffusion region in such a wafer, or a P-type epitaxial layer epitaxially grown on the wafer. The STI region 190 may be formed by shallow trench isolation (STI), but is not limited thereto.

A first buried layer 111 and a second buried layer 113 may be in the substrate 101. For example, the first buried layer 111 may be above the second buried layer 113. In addition, a high-voltage well 120 may be connected to the second buried layer 113. The high-voltage well 120 comprises an ion implantation region L) having a second conductivity type, and may be in the substrate 101 and on the second buried layer 113. The aforementioned first buried layer 111 may comprise an impurity doped region having a first conductivity type, and the second buried layer 113 may comprise an impurity doped region having a second conductivity type. It should be noted that the first buried layer 111 and the high-voltage well 120 are not essential components of the present disclosure and may be omitted in some cases.

A deep well 130 may be in the substrate 101 and on the high-voltage well 120. The deep well 130 is connected (e.g., at one side) to the high-voltage well 120 and may have a second conductivity type. The deep well 130 may be directly connected to the second buried layer 113 in some cases.

In the deep well 130, for example, first and second wells 141 and 143 (together, well regions 140) having the second conductivity type are spaced apart (e.g., by an STI structure 190). A drain 151 may be in the first well 141, and a heavily doped region 153 may be in the second well 143. The drain 151 comprises a doped region having the second conductivity type and includes a higher concentration of impurities than the first well 141. The heavily doped region 153 also comprises a doped region having the second conductivity type and has a higher concentration of impurities than the second well 143.

The drain 151 and the heavily doped region 153 are preferably on or at the surface of the substrate 101. The above-described heavily doped region 153 functions as a guard ring together with the second well 143 and the high-voltage well 120 to reduce leakage current and improve safe operating area (SOA) conditions (e.g., of the corresponding DMOS transistor). The drain 151 may be electrically connected to a drain electrode, and the well 141 surrounding the drain 151 may comprise a drain extension region that may improve breakdown voltage characteristics of the corresponding high voltage (e.g., DMOS) semiconductor device.

A body region 160 is in the substrate 101 between adjacent gates 170 of adjacent high voltage (e.g., DMOS) semiconductor devices. The body region 160 comprises a heavily doped region having the first conductivity type, and may be spaced apart from the deep well 130 (e.g., by channels [or portions thereof] of the adjacent high voltage semiconductor devices). A source 163 is in the body region 160 and on or at the surface of the substrate 101. The source 163 comprises a heavily doped region having the first conductivity type and may be electrically connected to a source electrode. In addition, a body contact 161 may be in the body region 160 and adjacent to or in contact with the source 163. The body contact 161 may comprise a heavily doped region having the first conductivity type.

A gate electrode 170 is on or above the substrate 101. To be specific, the gate electrode 170 may be between the drain 151 and the source 163 within the active region. The gate electrode 170 is over a channel region of a corresponding high voltage semiconductor device, and the voltage applied to the gate electrode 170 controls the conductivity of the channel region. The gate electrode 170 may comprise, for example, conductive polysilicon, a metal, a conductive (e.g., refractory) metal nitride, a conductive (e.g., refractory) metal silicide, or a combination thereof, and may be formed by chemical vapor deposition (CVD), physical vapor deposition (PVD, such as sputtering or evaporation), atomic layer deposition (ALD), metal-organic atomic layer deposition (MOALD), metal-organic chemical vapor deposition (MOCVD), etc., but is not limited thereto.

A gate insulation film 171 is between the gate electrode 170 and the surface of the substrate 101, and the gate insulation film 171 may comprise a silicon oxide (e.g., silicon dioxide) layer, a high-k insulator layer (e.g., HfO₂, hafnium silicate, ZrO₂, zirconium silicate, etc., which may or may not be nitrided), or a combination thereof. The gate insulation film 171 may be formed by ALD, CVD, or PVD.

One or more sidewalls of the gate electrode 170 may have a gate spacer 173 thereon or in contact therewith. The gate spacer 173 may comprise a nitride film (e.g., silicon nitride), an oxide film (e.g., silicon dioxide), or a combination thereof. The gate spacer 173 may also be on one or more sidewalls of a dummy gate 175 to be described later.

In addition, referring to FIG. 3, a dummy gate 175 may be on the substrate 101, overlapping the STI region 190 (to be described later). The dummy gate 175 may comprise the same material as the gate electrode 170, and may also include a thin insulating layer between this material and the surface of the substrate 101. The pre-DTI region 1911 of the isolation region 191 may penetrate or pass through the dummy gate 175 and the first isolation region 190. It should be noted that the dummy gate 175 is not an essential component of the present disclosure. The dummy gate 175 may have a relatively large width compared to the pre-DTI region 1911.

Referring to FIGS. 2 and 3, an interlayer dielectric 180 on the substrate 101 may completely cover the gate electrode 170, dummy gate 175, and pre-DTI region 1911. The interlayer dielectric 180 may comprise a borophosphosilicate glass (BPSG) film, a borosilicate glass (BSG) film, a phosphosilicate glass (PSG) film, a silicon oxide film formed from tetraethyl orthosilicate (TEOS), an undoped silicon dioxide film (e.g., formed from silane [SiH₄] gas), a silicon nitride film, a combination thereof, etc., but the scope of the present disclosure is not limited thereto.

The STI region 190 has a predetermined depth (e.g., from the surface of the substrate 101). The STI region 190 is an isolation layer defining the active region as described above, and may be formed, for example, by STI. In addition, the isolation region 191 may overlap (e.g., be completely within the area of) the STI region 190. The isolation region 191 includes a DTI structure, and it is preferable that the DTI structure (e.g., 1913) overlaps with the STI region 190 in order to maintain the area of the active region.

The isolation region 191 may include the pre-DTI region 1911 and the DTI region 1913. The pre-DTI region 1911 penetrates or passes through the STI region 190, and the dummy gate 175 if present. The pre-DTI region 1911 may have a lowermost surface substantially the same as or adjacent to the lowermost surface of the STI region 190.

The pre-DTI region 1911 may have a width that is narrower than the width of the STI region 190 and/or the dummy gate 175. The DTI region 1913 may be connected to the pre-DTI region 1911 (e.g., at a lowermost surface). The DTI region 1913 may have sidewalls that are substantially straight (e.g., in the vertical direction) or that may be sloped or inclined, but are not limited thereto. In addition, the DTI region 1913 has a width narrower than that of the pre-DTI region 1911. It is preferable that both the pre-DTI region 1911 and the DTI region 1913 be filled with the same dielectric material (e.g., that constituting the interlayer dielectric 180).

An air gap A is in the isolation region 191. For example, the air gap A may be adjacent to the lowermost surface of the DTI region 1913, through part or all of the DTI region 1913, and optionally into the pre-DTI region 1911. Preferably, the air gap A does not extend to the upper part of the upper region 1911. This is to prevent a metal such as tungsten (W) from entering the air gap A in a subsequent contact formation process, resulting in deterioration of device characteristics.

As previously described, in the present disclosure, the isolation region 191 may include (or be divided into) the pre-DTI region 1911 and the DTI region 1913. When forming a DTI region in a single etching process and filling the trench (instead of as taught by the present disclosure, in which the isolation region 191 includes two regions as described above), there is a technical limitation in the formation of the trench depth. That is, when the DTI region is formed by etching the substrate 101 in a single process, it is difficult to form the DTI region sufficiently deep so that adjacent devices are sufficiently electrically isolated.

FIG. 4 is a reference view showing isolation characteristics according to the depth of the isolation region (or a DTI region).

Referring to FIG. 4, when the substrate 101 is relatively thick (e.g., in order to achieve a breakdown voltage [BV] of 100V or more), the corresponding DTI region may not be sufficiently deep, which leads to problems that the breakdown voltage deteriorates due to an increase in the area of the electric field to the region below the DTI region, and the leakage current increases. In addition, in order to reduce or prevent transmission of noise between adjacent devices, the distance increases between adjacent devices, and thus the overall chip size increases.

Referring to FIGS. 2 and 3, in order to prevent the above-described problem, in the semiconductor device 1 according to one or more embodiments of the present disclosure, the isolation region 191, particularly the DTI region 1913, is sufficiently deep to electrically isolate adjacent devices, maintain breakdown voltage characteristics, and minimize device area by virtue of the DTI region 1913 having a relatively narrow width W2 and the pre-DTI region 1911 having a relatively large width W1 in the isolation region 191. As previously described, it is preferable that the depth of the isolation region 191 is approximately 30 μm or more and 40 μm or less from the surface (e.g., the uppermost surface) of the substrate 101. Referring to FIG. 4, it can be seen that the isolation region 191 according to one or more embodiments of the present disclosure improves the isolation characteristics between adjacent devices.

In addition, the pre-DTI region 1911 of the isolation region 191 may not penetrate or completely pass through the interlayer dielectric 180, but rather, may partially be in the interlayer dielectric 180. For example, the isolation region 191 may be formed before the interlayer dielectric 180 is deposited on the substrate 101. This can result in the following advantages.

Generally, when the isolation region 191 is formed by etching the interlayer dielectric 180 on the substrate 101, the excess material on the interlayer dielectric 180 may be removed by CMP. In such a case, an etch stop layer such as a SiN layer is first deposited on the interlayer dielectric 180 (e.g., to protect the interlayer dielectric 180 during CMP), then removed after the isolation region 191 is formed. Accordingly, the necessity of etch stop layer deposition and etching complicate the manufacturing process.

Moreover, after depositing the etch stop layer on the interlayer dielectric 180, when a subsequent process such as heat treatment is performed, Si—H bonds or N—H bonds (e.g., at an interface of the SiN layer) may be broken, so that hydrogen ions and/or radicals diffuse towards the substrate 101 and change the substrate interface, which may lead to reliability problems.

To solve this problem, in the semiconductor device 1 according to embodiments of the present disclosure, the isolation region 191 may be formed before the gate electrode 170. That is, after depositing an insulating layer on the gate layer (e.g., a polysilicon film on the substrate 101), the gate layer and the substrate 101 are etch to form a trench for the isolation region 191, and during the CMP process for removing the insulating layer, the gate layer effectively functions as an etch stop layer. Accordingly, since a separate etch stop layer is not required, it is possible to prevent the above-mentioned problems from occurring.

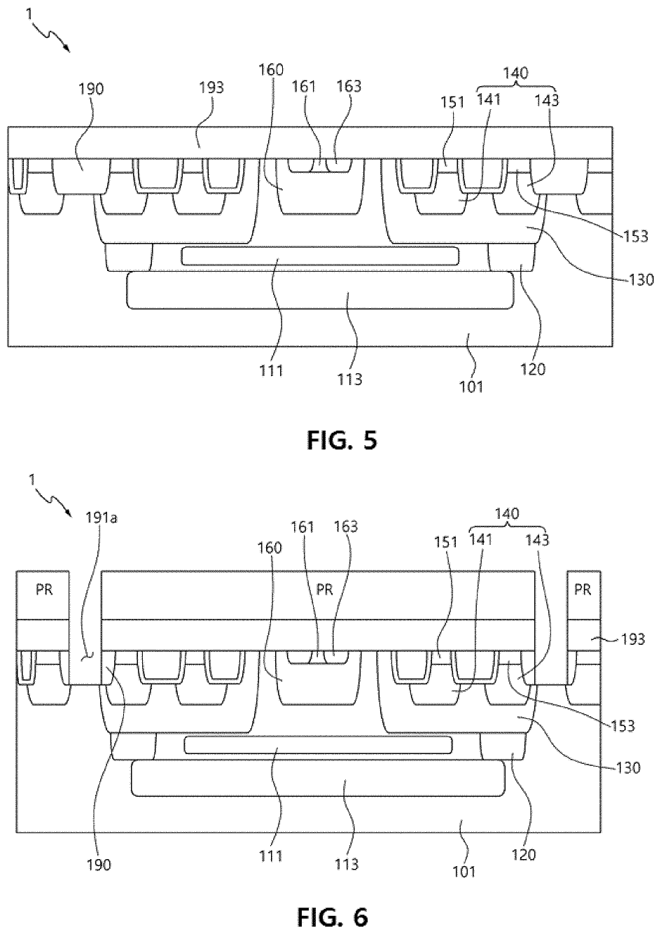

FIGS. 5 to 13 are cross-sectional views showing a method of manufacturing a semiconductor device according to one or more embodiments of the present disclosure.

Hereinafter, the method of manufacturing a semiconductor device according to one or more embodiments of the present disclosure will be described in detail with reference to the accompanying drawings. For convenience of description, descriptions of wells, buried layers, the source, and the drain in the substrate will be omitted, while the processes after formation of the STI region 190 will be mainly described.

Referring to FIG. 5, first, a gate layer 193 is blanket deposited on the substrate 101 containing the STI region 190. The gate layer 193 may comprise, for example, a polysilicon film.

Thereafter, referring to FIG. 6, the gate layer 193 and the STI region 190 are etched. To be specific, after a photoresist layer PR is patterned to expose an area of the gate layer 193 corresponding to the pre-DTI region 1911, the gate layer 193 and the isolation region 191 are etched (e.g., by dry or reactive ion etching). Accordingly, a first trench 191a is formed for the pre-DTI region 1911. Preferably, the width of the first trench 191a is smaller than the width of the isolation region 191. After the first trench 191a is formed, the photoresist pattern PR is removed, for example, by conventional stripping and cleaning.

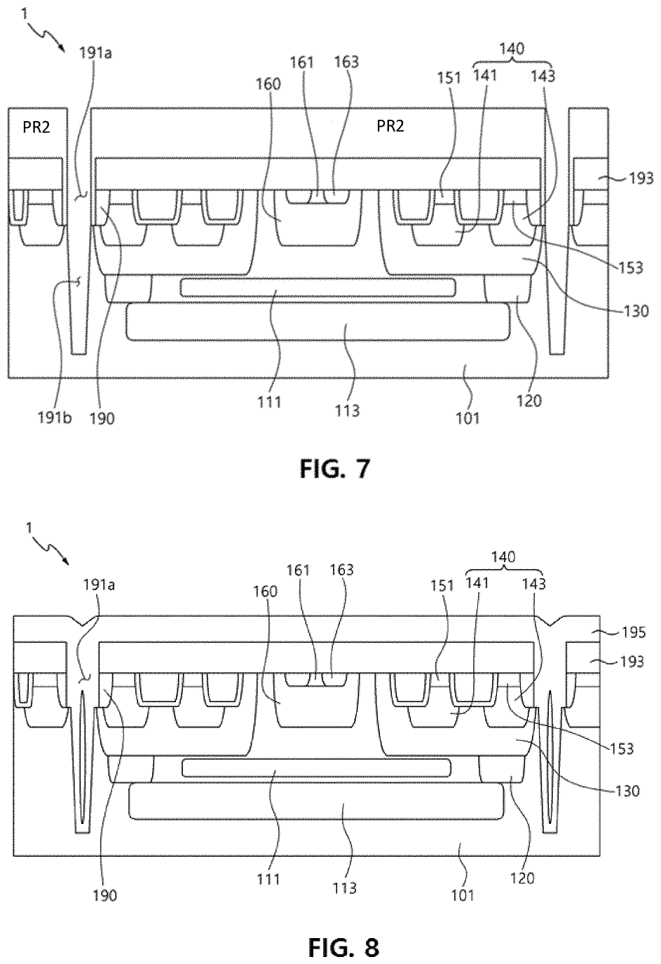

Thereafter, referring to FIG. 7, a second trench 191b for the DTI region 193 is formed in the substrate 101. The second trench 191b preferably has a smaller width than the first trench 191a, and the second trench may be etched to a depth of 30-40 μm from the surface of the substrate 101. In addition, sidewalls of the second trench 191b may be sloped or inclined (e.g., as they extend into the substrate 101). The process of forming the second trench 191b includes, for example, patterning a photoresist layer to form a photoresist pattern PR2 having a predetermined thickness on the gate layer 193 and along the sidewalls of the gate layer 193 and the first trench 191a. Then, the second trench 191b may be formed by etching the exposed substrate 101. Then, the photoresist pattern PR2 is removed by stripping and cleaning.

Thereafter, referring to FIG. 8, a first insulating layer 195 is deposited on the gate layer 193 and in the first trench 191a and the second trench 191b. The first insulating layer 195 may comprise, for example, a TEOS layer, but the scope of the present disclosure is not limited thereto. The first insulating layer 195 is deposited on the sidewalls of the first trench 191a and the second trench 191b, as well as on the gate layer 193 and at edge portions of the first trench 191a and the gate layer 193.

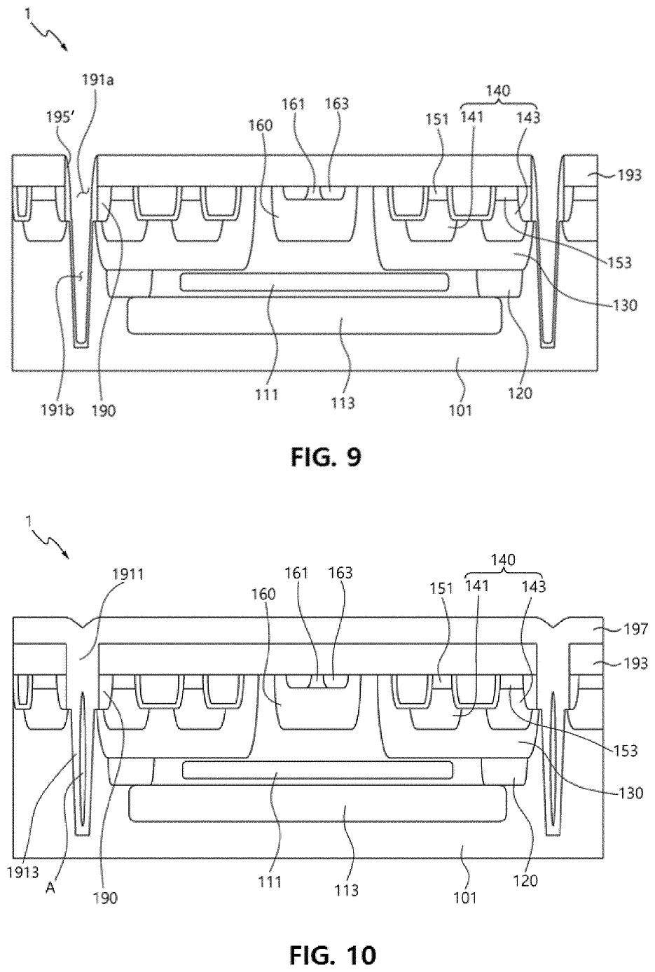

Subsequently, referring to FIG. 9, the first insulating layer 195 is completely removed from the uppermost surface of the gate layer 193 and partially removed from the first and second trenches 191a-b by anisotropic etching (e.g., an etch-back process). By partially removing the first insulating layer 195 in the first trench 191a and the second trench 191b, a sidewall portion of the first insulating layer 195′ may remain along the walls of in the first trench 191a and the second trench 191b. The remaining first insulating layer 195′ may have a predetermined thickness in the second trench 191b, and may have a shape similar to that of a gate sidewall spacer (e.g., 173; see FIGS. 2, 3 and 12).

Thereafter, referring to FIG. 10, a second insulating layer 197 is deposited on the gate layer 193 and in the first trench 191a and the second trench 191b along the remaining first insulating layer 195′. An air gap A may form in the second insulating layer 197 in the second trench 191b and, in some cases, the air gap A may extend to or into the first trench 191a. The air gap A may function as an additional insulator to reduce or prevent transmission of noise between adjacent devices and/or improve the electrical stability of the device 1. By this process, the pre-DTI region 1911 and the DTI region 1913 may be formed. The second insulating layer 197 may be deposited on the remaining first insulating layer 195′ in the first trench 191a and the second trench 191b.

It is preferable that the air gap A has an uppermost end below the pre-DTI region 1911 at an appropriate depth or height to prevent tungsten (W) or the like from entering the air gap A in a subsequent process. The second insulating layer 197 may comprise the same material as the first insulating layer 195, but there is no limitation thereto, and any oxide or other conformally-depositable insulator material may be used.

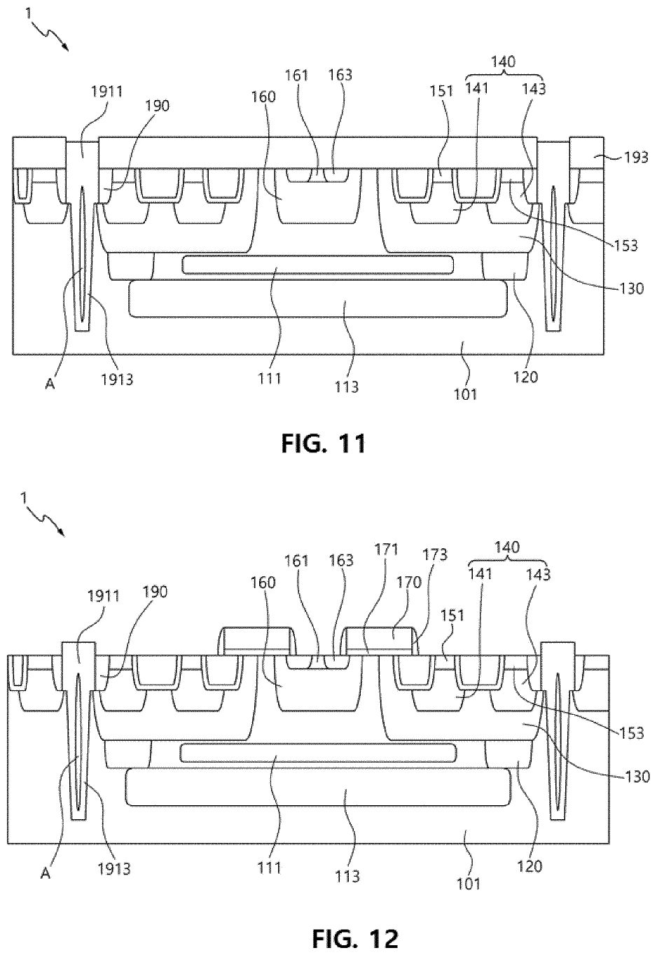

Referring to FIG. 11, after the isolation region 191 is formed, the excess second insulating layer 197 on the gate layer 193 is removed. This may be performed by polishing (e.g., CMP) using the gate layer 193 as an etch stop or polishing stop layer.

Thereafter, referring to FIG. 12, the gate layer 193 on the substrate 101 is photolithographically patterned and etched to form the gate electrode 170. In addition, the dummy gate 175 may be formed on or over the pre-DTI region 1911 in this process. The gate electrode 170 and the dummy gate 175 may be formed first by patterning a photoresist layer on the gate layer 193, then etching the exposed gate layer 193. A detailed description thereof will be omitted.

Then, the gate spacer 173 is formed, for example, by blanket-depositing or conformally depositing one or more insulator layers on the patterned gate layer 193 and (when present) the dummy gate 175, then anisotropically etching the one or more insulator layers (e.g., until an uppermost surface of the patterned gate layer 193 and [when present] the dummy gate 175 are exposed).

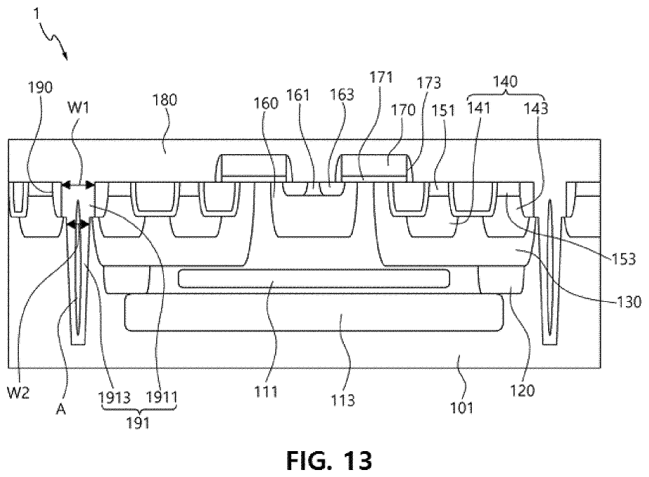

After the gate spacer 173 is formed, referring to FIG. 13, the interlayer dielectric 180 is deposited on the substrate 101 to cover the pre-DTI region 1911 and the gate electrode(s) 170. The interlayer dielectric 180 may be formed, for example, by blanket-depositing a borophosphosilicate glass (BPSG) film and a tetra ethyl ortho silicate (TEOS) film onto the pre-DTI region 1911, the gate electrode(s) 170, the dummy gate 175 (when present), and the exposed areas of the substrate 101, but the scope of the present disclosure is not limited thereto.

As described above, since the interlayer dielectric 180 completely covers the isolation region 191, it is possible to prevent contact material such as tungsten (W) from entering the isolation region 191 or the air gap A in a subsequent contact-forming process, and thereby prevent deterioration of device characteristics.

The above detailed description is illustrative of the present disclosure. In addition, the above description shows and describes various embodiments of the present disclosure, and the present disclosure can be used in various other combinations, modifications, and environments. In other words, changes or modifications are possible within the scope of the concept of the disclosure disclosed herein, the scope equivalent to the written disclosure, and/or within the scope of skill or knowledge in the art. The above-described embodiment describes various manners and/or states for implementing the technical idea of the present disclosure, and various changes for specific application field and/or uses of the present disclosure are possible. Accordingly, the detailed description of the present disclosure is not intended to limit the present disclosure to the disclosed embodiments.

What is claimed is:

1. A semiconductor device, comprising:
a substrate;
a gate electrode on the substrate;
an STI region in the substrate;
an isolation region comprising:
a pre-DTI region that at least partially overlaps with the STI region; and
a DTI region extending from the pre-DTI region into the substrate; and
an interlayer dielectric on the substrate, covering the interlayer dielectric.

2. The semiconductor device of claim 1, wherein at least part of the isolation region passes through the interlayer dielectric.

3. The semiconductor device of claim 1, wherein the DTI region has a smaller width than that of the pre-DTI region.

4. The semiconductor device of claim 1, further comprising:
an air gap in the isolation region, at least partially below the pre-DTI region.

5. The semiconductor device of claim 1, wherein each of the gate electrode and at least part of the DTI region above an uppermost surface of the substrate.

6. The semiconductor device of claim 1, further comprising:
a first buried layer having a second conductivity type in the substrate;
a deep well directly or indirectly connected to the first buried layer;
a first well in the deep well;
a drain in the first well and at a surface of the substrate;
a body region having a first conductivity type in the substrate; and
a source in the body region and at the surface of the substrate.

7. The semiconductor device of claim 6, further comprising:
a second buried layer having the first conductivity type in the substrate; and
a high-voltage well having the second conductivity type connected to the second buried layer and the deep well.

8. The semiconductor device of claim 1, wherein the pre-DTI region is at least partially below an adjacent gate electrode.

9. The semiconductor device of claim 1, further comprising:
a dummy gate on the STI region,
wherein the pre-DTI region at least partially overlaps the dummy gate.

10. The semiconductor device of claim 6, wherein the DTI region has a lowermost surface below the second buried layer.

11. A method of manufacturing a semiconductor device, the method comprising:
depositing a gate layer on a substrate containing a shallow trench isolation (STI) region;
forming a first trench by etching the gate layer and the STI region;
forming a second trench by etching the substrate under or exposed by the first trench;
depositing a first insulating layer along sidewalls of the first trench and the second trench; and
forming an isolation region by filling the first trench and the second trench with a second insulating layer.

12. The method of manufacturing a semiconductor device of claim 11, further comprising, after forming the isolation region:
forming a gate electrode by etching the gate layer.

13. The method of manufacturing a semiconductor device of claim 12, further comprising:
depositing an interlayer dielectric on the substrate to cover the gate electrode and the isolation region.

14. The method of manufacturing a semiconductor device of claim 12, wherein:
etching the gate layer may further form a dummy gate on the STI region.

15. A method of manufacturing a semiconductor device, the method comprising:
depositing a gate layer on a substrate containing a shallow trench isolation (STI) region;
forming an isolation region containing an air gap, wherein at least part of the isolation region passes through the gate layer and the STI region;
forming a gate electrode by etching the gate layer; and
depositing an interlayer dielectric on the gate electrode and the substrate.

16. The method of manufacturing a semiconductor device of claim 15, wherein forming the isolation region comprises:
forming a pre-deep trench isolation (DTI) region at least partially overlapping the STI region; and
forming a DTI region to a predetermined depth in the substrate.

17. The method of manufacturing a semiconductor device of claim 16, wherein forming the pre-DTI region comprises:
forming a first trench by etching the gate layer exposed by a first photoresist pattern, and
forming the DTI region comprises:
forming a second trench having a smaller width than that of the first trench by etching the substrate exposed by a second photoresist pattern on the gate layer and on sidewalls of the first trench.

18. The method of manufacturing a semiconductor device of claim 17, wherein forming the pre-DTI region and forming the DTI region further comprise:
depositing a first insulating layer on the gate layer and in the first and second trenches;
anisotropically etching the first insulating layer on the gate layer;
depositing a second insulating layer on the gate layer and in the first and second trenches; and
removing the second insulating layer on the gate layer.

19. The method of manufacturing a semiconductor device of claim 15, wherein the interlayer dielectric is deposited after forming the isolation region.

20. The method of manufacturing a semiconductor device of claim 15, wherein the isolation region has a lowermost surface at a depth of about 30 μm or more from a surface of the substrate.
